(19) United States
(12) Patent Application Publication
(10) Pub. No.: US 2022/0216437 A1
(43) Pub. Date: Jul. 7, 2022

(54) ORGANIC ELECTROCEHEMICAL TRANSISTOR DEVICE AND MANUFACTURING MEHOD FOR SAME

(71) Applicant: FLEXOLUTION, Yongin-si, Gyeonggi-do (KR)

(72) Inventors: Sung Soo KIM, Daejeon (KR); Jung Won LEE, Seoul (KR)

(73) Assignee: FLEXOLUTION, Yongin-si, Gyeonggi-do (KR)

(21) Appl. No.: 17/609,402

(22) PCT Filed: Aug. 20, 2019
(86) PCT No.: PCT/KR2019/010584

§ 371 Date: Nov. 7, 2021

(30) Foreign Application Priority Data
May 8, 2019 (KR) 10-2019-0053787

(51) Int. Cl. H01L 51/05; H01L 51/00; H01L 51/10

(52) U.S. Cl. CPC H01L 51/0566; H01L 51/0008; H01L 51/0037; H01L 51/105; H01L 51/0097

(57) ABSTRACT

Proposed are an organic electrochemical transistor device and a manufacturing method for same, the organic electrochemical transistor device comprising: a substrate; a source electrode and a drain electrode, formed on an upper surface of the substrate; and a poly(hydroxymethyl-EDOT) polymer active layer formed on the upper surface of the substrate and electrically in contact with the source electrode and the drain electrode. According to the embodiment, an organic electrochemical transistor device with high sensitivity characteristics and desirable aqueous solution stability and mechanical stability can be provided.

### CROSS-REFERENCE TO RELATED APPLICATION

The present application is a U.S. national phase application of PCT International Application PCT/KR2019/010584, filed Aug. 20, 2019, which claims priority to Korean Patent Application No. 10-2019-0053787, filed May 8, 2019, the entire contents of each of which are herein incorporated by reference.

### TECHNICAL FIELD

The present disclosure relates to an organic electrochemical transistor device and a manufacturing method for the same and, more particularly, to an organic electrochemical transistor device using a poly(hydroxymethyl-EDOT) film as an active layer and a manufacturing method for the same.

### BACKGROUND ART

An organic electrochemical transistor (OECT) is a transistor device including a polymer active layer in contact with an electrolyte. Since the polymer active layer contains electric charges, when a voltage is applied between a source electrode and a drain electrode, current flows through the polymer active layer. That is, the polymer active layer forms a channel of the transistor, and the current flowing through the polymer active layer is referred to as drain current. The drain current is changed in response to cations or anions being injected from the electrolyte to the polymer active layer depending on an applied gate voltage, and when the gate voltage is removed, an original drain current value is regained.

The organic electrochemical transistor may be used in a variety of chemical and biosensors. In particular, the organic electrochemical transistor is suitable to be manufactured as a wearable device that is flexible and attachable to a human body. Thus, various researches are being conducted for applying the organic electrochemical transistor to a variety of fields, such as healthcare, fitness, information, industrial, and military fields.

To be manufactured as a wearable device, the organic electrochemical transistor should be able to be realized as a flexible device. In addition, the organic electrochemical transistor should have a small size and a high-sensitivity characteristic able to detect a trace amount of a target substance, as well as stability in an aqueous solution, a rapid response time, and mechanical durability.

However, an organic electrochemical transistor device having high performance at a commercially available level has not been yet developed. Although there has been a number of researches on an organic electrochemical transistor device using poly(3,4-ethylenedioxythiophene) polystyrene sulfonate (hereinafter, referred to as “‘PEDOT:PSS”), i.e., a representative conductive polymer, there are still limitations in that the conductivity is not yet sufficient and stability in an aqueous solution and mechanical durability are unsatisfactory. Therefore, in order to commercialize a high-performance organic electrochemical transistor device, significant improvements in the material and a synthesis method for the same are required.

### DISCLOSURE

### Technical Problem

Accordingly, the present disclosure has been made keeping in mind the above problems occurring in the prior art, and an objective of the present disclosure is to provide an organic electrochemical transistor device having superior high-sensitivity characteristics, aqueous solution stability, and mechanical durability and a manufacturing method for the same. Specifically, it is intended to provide a polymer active layer material suitable to a high-performance organic electrochemical transistor device and a synthesis method for the same.

It is also intended to provide a conductive polymer electrode material suitable for a high-performance organic electrochemical transistor device and a synthesis method for the same.

It is also intended to provide a high-performance organic electrochemical transistor device composed of only a polymer material.

It is also intended to provide a biosensor device using an organic electrochemical transistor device.

The objectives of the present disclosure are not limited to the aforementioned description, and other objectives and advantages of the present disclosure not explicitly described will be clearly understood from the description provided hereinafter.

### Technical Solution

In order to accomplish the above objective, the present disclosure provides an organic electrochemical transistor device including: a substrate; a source electrode and a drain electrode provided on a top surface of the substrate; and a poly(hydroxymethyl-EDOT) polymer active layer provided on the top surface of the substrate and in electrical contact with the source electrode and the drain electrode.

The substrate may be a flexible substrate. Each of the source electrode and the drain electrode may be implemented as a PEDOT film doped with dodecyl sulfate. Here, the PEDOT film may be formed by gas phase polymerization using dodecyl sulfate metal salt, such as Fe(DS)₃, as an oxidizer. The content of the dodecyl sulfate in the PEDOT film may range from 5 to 50%.

In the organic electrochemical transistor device according to embodiments of the present disclosure, the maximum transconductance value may be 6 mS or more.

In addition, a change in the transconductance after immersion in an aqueous solution for 48 hours or more may be 10% or less. A change in the transconductance after a 10,000 times or more bending test may be 30% or less.

A biosensor according to embodiments of the present disclosure may include the above-described organic electrochemical transistor device.

Here, a bioreceptor may be fixed to the poly(hydroxymethyl-EDOT) polymer active layer. The biosensor may further include a linker for binding the bioreceptor to the polymer active layer and a cross-linker for binding the bioreceptor to the linker. Here, the linker may be an APS self-assembled molecular layer, and the cross-linker may be sulfo-SMCC.

A method of manufacturing an organic electrochemical transistor device according to embodiments of the present disclosure may include may include: an electrode forming step of forming a source electrode and a drain electrode on a top surface of a substrate; and an active layer forming step of forming a poly(hydroxymethyl-EDOT) polymer active layer on the top surface of the substrate to be in electrical contact with the source electrode and the drain electrode. The active layer forming step may be performed on the substrate to which a mixed oxidizer is applied by gas phase polymerization.

Here, the mixed oxidizer used in the active layer forming step may include FeCl₃, DUDO, and PEG-PPG-PEG. The composition of the mixed oxidizer may include FeCl₃.6H₂O 0.5 to 8 mmol, DUDO 0.1 to 0.6 mmol, and PEG-PPG-PEG 0.005 to 0.3 mmol. Particularly, the composition of the mixed oxidizer may include FeCl₃.6H₂O 5 to 6 mmol, DUDO 0.3 to 0.4 mmol, and PEG-PPG-PEG 0.1 to 0.2 mmol.

In addition, the electrode forming step may include: a step of coating an oxidizer containing dodecyl sulfate metal salt on a substrate; a step of forming a PEDOT film on the oxidizer-coated substrate by gas phase polymerization; and cleaning and drying the PEDOT film.

Here, the dodecyl sulfate metal salt may contain Fe(DS)₃.

### Advantageous Effects

According to the present disclosure, by forming the polymer active layer from poly(hydroxymethyl-EDOT), the organic electrochemical transistor device having superior high-sensitivity characteristics, aqueous solution stability, and mechanical durability and the manufacturing method for the same may be provided.

In addition, according to the present disclosure, by forming the source electrode and the drain electrode using the poly(3,4-ethylenedioxythiophene) (hereinafter, referred to as “PEDOT”) film in which dodecyl sulfate is contained as a dopant, the high-performance organic electrochemical transistor device suitable for manufacture of a flexible device and the manufacturing method for the same may be provided.

In addition, according to the present disclosure, by forming the poly(hydroxymethyl-EDOT) polymer active layer, as well as the source electrode and the drain electrode in which dodecyl sulfate is contained as a dopant, on the polymer substrate, the high-performance organic electrochemical transistor device composed of only a polymer material may be provided.

Furthermore, according to the present disclosure, by fixing the bioreceptor to a hydroxyl group (—OH) present in the poly(hydroxymethyl-EDOT) polymer active layer of the organic electrochemical transistor device, the high-performance biosensor may be provided.

However, the effects of the present disclosure are not limited to the aforementioned description, and other effects of the present disclosure not explicitly described will be clearly understood from the description provided hereinafter by those skilled in the technical field, to which the present disclosure pertains.

### DESCRIPTION OF DRAWINGS

FIG. 1 is a cross-sectional view of an organic electrochemical transistor device according to embodiments of the present disclosure;

FIG. 2 is a flowchart of a method of manufacturing an organic electrochemical transistor device according to embodiments of the present disclosure;

FIG. 3 is a flowchart illustrating an embodiment of the electrode forming step;

FIG. 4 is a flowchart of an embodiment of manufacturing a dodecyl sulfate metal salt oxidizer;

FIG. 5 is a flowchart specifically illustrating a method of manufacturing an Fe(DS)₃ oxidize;

FIG. 6 is a flowchart illustrating an active layer forming step (S22);

FIG. 7 is an electric conductivity graph of a PEDOT film according to the concentration of an Fe(DS)₃ oxidizer included in an oxidizer solution;

FIG. 8 is a result of observing surfaces of poly(hydroxymethyl-EDOT) thin films according to Example and Comparative Example using an optical microscope;

FIG. 9 is a conceptual view of the operation of the organic electrochemical transistor device;

FIG. 10 is a measurement result of characteristics of an organic electrochemical transistor device according to embodiments of the present disclosure;

FIG. 11 is a measurement result of aqueous solution stability of an organic electrochemical transistor device according to embodiments of the present disclosure;

FIG. 12 is a measurement result of mechanical durability of an organic electrochemical transistor device according to embodiments of the present disclosure; and

FIG. 13 is a result of observing the biosensor according to embodiments of the present disclosure using an optical microscope.

### MODE FOR INVENTION

Hereinafter, the present disclosure will be described in detail with reference to the accompanying drawings. Although the following description includes specific embodiments, the present disclosure is not limited or restricted thereby. In the following description of the present disclosure, a detailed description of related known technology will be omitted in the situation in which the subject matter of the present disclosure may be rendered rather unclear thereby.

The present disclosure proposes a poly(hydroxymethyl-EDOT) polymer active layer as a polymer active layer enabling an organic electrochemical transistor device to be realized at a commercially available level and a synthesizing method for the same.

In addition, the present disclosure proposes a PEDOT electrode doped with dodecyl sulfate as an electrode material suitable for realizing a high performance organic electrochemical transistor into a flexible device and a synthesizing method for the same.

Furthermore, the present disclosure proposes an organic electrochemical transistor device manufactured by forming a poly(hydroxymethyl-EDOT) polymer active layer and a PEDOT electrode doped with dodecyl sulfate on a flexible substrate and a manufacturing method for the same.

According to the present disclosure, it is possible to produce an organic electrochemical transistor device having significantly improved high-sensitivity characteristics, aqueous solution stability, and mechanical durability compared to those of a related-art device using a conductive polymer such as PEDOT:PSS.

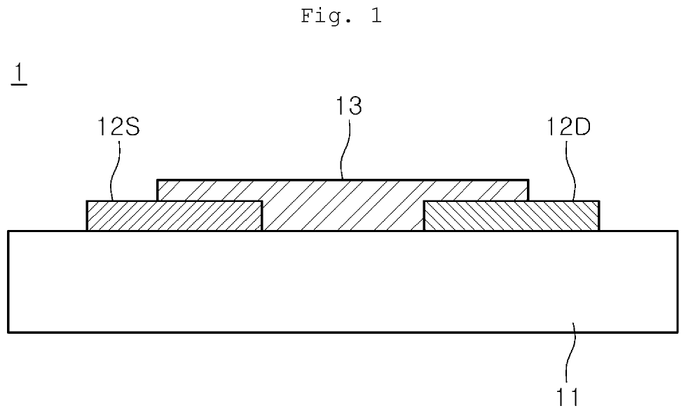

FIG. 1 is a cross-sectional view of an organic electrochemical transistor device according to embodiments of the present disclosure.

Referring to FIG. 1, an organic electrochemical transistor device 1 according to embodiments of the present disclosure includes a substrate 11, a source electrode 12S and a drain electrode 12D provided on the top surface of the substrate 11, and a polymer active layer 13 provided on the top surface of the substrate 11 to be in electrical contact with the source electrode 12S and the drain electrode 12D.

The substrate 11 may be implemented as a polymer film, a glass substrate, a silicon substrate, and the like. In particular, the substrate 11 may be implemented as a polymer film made of, for example, polyethylene terephthalate (PET) or polyimide (PI), in order to be used for a flexible device.

The source electrode 12S and the drain electrode 12D are provided on the top surface of the substrate 11 as patterns spaced apart and electrically isolated from each other. Each of the source electrode 12S and the drain electrode 12D may be implemented as a metal electrode made of gold (Au) or the like or a conductive polymer electrode made of PEDOT:PSS or the like. In order to be used for a flexible device, each of the source electrode 12S and the drain electrode 12D may be implemented as a conductive polymer electrode having high flexibility. In particular, each of the source electrode 12S and the drain electrode 12D may be implemented as a PEDOT electrode doped with dodecyl sulfate. The dodecyl sulfate-doped PEDOT not only has superior electric conductivity but also is superior in mechanical durability and aqueous solution resistance. Thus, the dodecyl sulfate-doped PEDOT exhibits more superior characteristics as an electrode material for the organic electrochemical transistor device than PEDOT:PSS widely studied as a conductive polymer.

Formula 1 below is a chemical formula of PEDOT and dodecyl sulfate dopant constituting dodecyl sulfate-doped PEDOT.

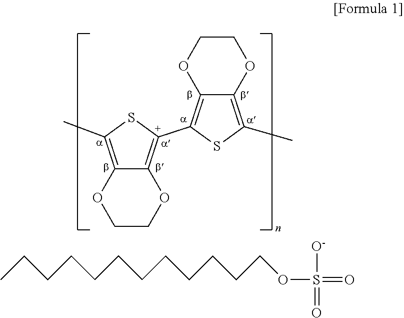

The dodecyl sulfate content in the PEDOT electrode doped with dodecyl sulfate according to embodiments of the present disclosure may be in the range of 5 to 50%, preferably, 20 to 45%, and more preferably, 30 to 40%.

The polymer active layer 13 is provided in a poly(hydroxymethyl-EDOT) pattern on the top surface of the substrate 11. The polymer active layer 13 is patterned to be in electrical contact with the source electrode 12S and the drain electrode 12D. The polymer active layer 13 may function as a channel of the organic electrochemical transistor device 1.

The electric conductivity of the polymer active layer 13 according to embodiments of the present disclosure may be 500 S/cm or more, and preferably, 1,000 S/cm or more.

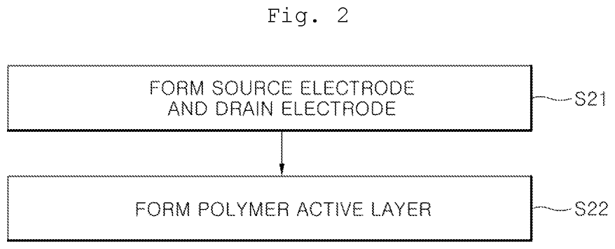

FIG. 2 is a flowchart of a method of manufacturing an organic electrochemical transistor device according to embodiments of the present disclosure. The method of manufacturing an organic electrochemical transistor device according to embodiments of the present disclosure may include: electrode forming step S21 of forming a source electrode and a drain electrode on the top surface of a substrate; and active layer forming step S22 of forming a polymer active layer on the top surface of the substrate. In a structure in which the polymer active layer is formed on the top surface of the substrate before the source electrode and the drain electrode are formed on the polymer active layer differently from the structure in FIG. 1, the order of the step S21 and the step S22 may be changed.

The electrode forming step S21 is a step of forming the source electrode and the drain electrode of the organic electrochemical transistor device on the top surface of the substrate. Although a method of forming the electrode pattern is not specifically limited, a masking tape method of performing gas phase polymerization after covering top surface areas of the substrate, except for an area on which the electrode pattern is to be formed, with a tape may be used. The masking tape may be removed after the gas phase polymerization.

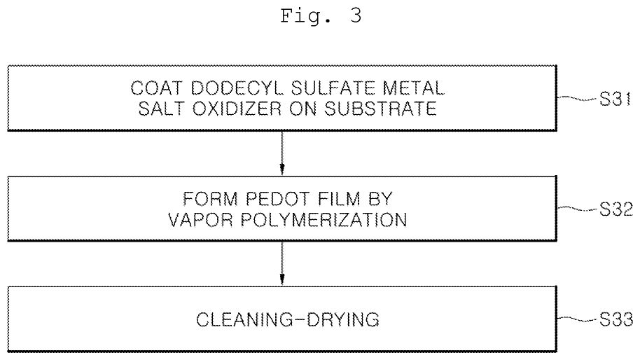

According to embodiments of the present disclosure, the electrode material may be dodecyl sulfate-doped PEDOT, and may be formed by gas phase polymerization. FIG. 3 is a flowchart illustrating an embodiment of the electrode forming step S21.

Described with reference to FIG. 3, the electrode forming step S21 according to embodiments of the present disclosure is a step of forming a PEDOT film doped with dodecyl sulfate. The electrode forming step S21 may include step S31 of coating the substrate with a dodecyl sulfate metal salt oxidizer, step S32 of forming a PEDOT film by gas phase polymerization, and cleaning-drying step S33.

First, the step S31 of coating the substrate with the dodecyl sulfate metal salt oxidizer is a step of coating the substrate with an oxidizer acting as a catalyst for forming the PEDOT film. Here, using dodecyl sulfate metal salt as the oxidizer may allow dodecyl sulfate to be doped in PEDOT in a step of forming the PEDOT film.

The oxidizer may be coated by spin coating or drop coating.

The oxidizer may be implemented as dodecyl sulfate metal salt having a chemical formula Mₓ(DS)_{y}. Here, DS may indicate dodecyl sulfate, and M may be a metal selected from among, but not limited to, Fe, Cr, Co, Ni, Mn, V, Rh, Au, Cu, or Mo. For example, the oxidizer may be Fe(DS)₃.

Afterwards, in the step S32, a substrate coated with an oxidizer film is mounted within a gas polymerization chamber. Here, the substrate may be mounted in the upper portion of the chamber such that the oxidizer film is directed downward. Vessels containing EDOT monomer and water, respectively, are disposed in the lower portion of the chamber. The chamber may be configured such that evaporated EDOT monomer and water reach the substrate. By the gas phase polymerization using this configuration, the PEDOT film is formed on the substrate.

The substrate having the PEDOT film formed thereon is unloaded from the gas polymerization chamber and cleaning and drying are performed thereon in step S33. The cleaning may be intended to remove excessive oxidizer and EDOT monomer remaining on the surface of the film, and may be performed using ethanol. After the cleaning, the drying may be performed at about 70° C. for 1 to 2 hours, thereby removing the cleaning agent.

Although not shown in FIG. 3, a step of attaching a masking tape to the substrate for the formation of the electrode pattern and removing the masking tape after the gas polymerization may further be included.

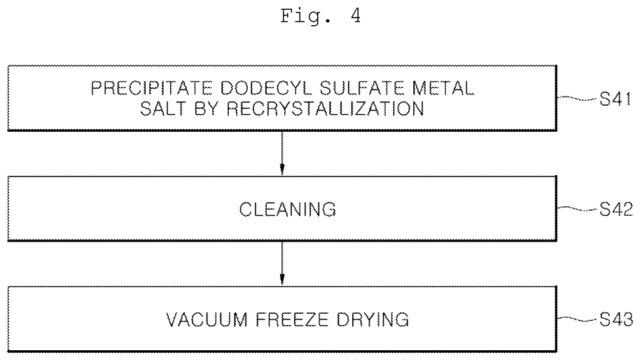

FIG. 4 is a flowchart of an embodiment of manufacturing the dodecyl sulfate metal salt oxidizer. Described with reference to FIG. 4, the dodecyl sulfate metal salt is precipitated by recrystallization in step S41. Here, the recrystallization may be a method of precipitating the dodecyl sulfate metal salt by adding a metal compound (e.g., a metal chloride) to a solution in which a dodecyl sulfate is dissolved. Here, the metal compound may be added to a solution in which the dodecyl sulfate is dissolved in the form of an aqueous solution. The metal compound may be added to the dodecyl sulfate solution while stirring the dodecyl sulfate solution so that the metal compound may be uniformly mixed.

The step S41 may further include a step of removing impurities. For example, the precipitate produced by adding the metal compound to the dodecyl sulfate solution may include impurities. Non-dissolved impurities may be removed by dissolving the precipitate with methanol or the like and performing centrifugation. From the solution from which impurities are removed, a final dodecyl sulfate metal salt precipitate may be produced.

Afterwards, the precipitated dodecyl sulfate metal salt is cleaned in step S42, and vacuum freeze drying is performed in step S43. The cleaning may be repeatedly performed using deionized water, and the vacuum freeze drying may be performed in a reduced-pressure atmosphere.

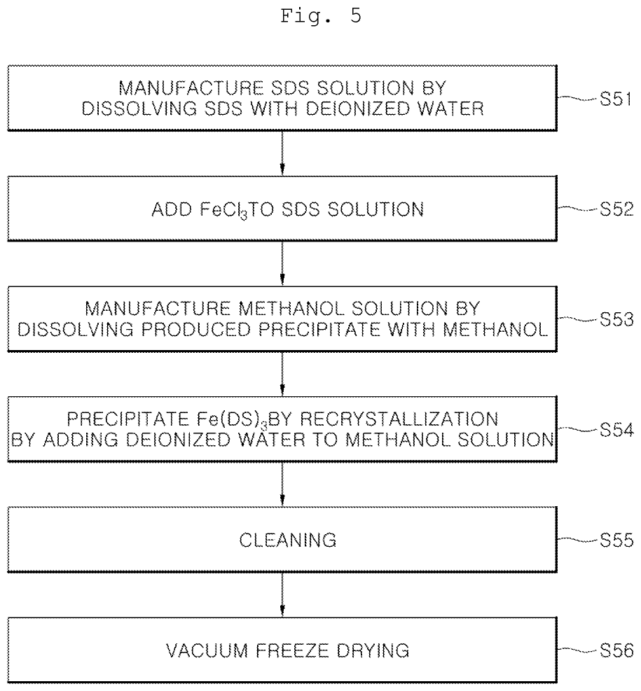

FIG. 5 is a flowchart more specifically illustrating a method of manufacturing an Fe(DS)₃ oxidizer in the dodecyl sulfate metal salt. Referring to FIG. 5, a sodium dodecyl sulfate (SDS) solution is manufactured by dissolving an SDS with deionized water (DI water) in step S51. Here, the dissolving may be performed with stirring until a transparent SDS solution is produced.

Afterwards, step S52 of adding FeCl₃ into the SDS solution is performed. FeCl₃ may be added in the form of an aqueous solution into the SDS solution.

Subsequently, the precipitate produced in the SDS solution in response to the addition of FeCl₃ is dissolved with methanol, thereby manufacturing a methanol solution in step S53. The precipitate may be dissolved with methanol after having been repeatedly cleaned with deionized water. Non-dissolved impurities may be removed from the methanol solution by performing high-speed centrifugation to the methanol solution.

Fe(DS)₃ recrystallization and precipitation is performed by adding deionized water to the methanol solution from which impurities are removed in step S54. Precipitated Fe(DS)₃ is repeatedly cleaned and then dried by vacuum freeze drying. Here, the drying may be performed for two days or more.

Returning to FIG. 2, after the electrode is manufactured by the above-described method, the active layer forming step S22 of forming a polymer active layer may be performed. The active layer forming step S22 is a step of forming a poly(hydroxymethyl-EDOT) active layer pattern on the top surface of the substrate on which the patterns of the source electrode and the drain electrode are formed. The poly(hydroxymethyl-EDOT) active layer may be formed by gas phase polymerization. Although methods of forming the active layer pattern are not specifically limited, a masking tape method of performing gas polymerization after covering top surface areas of the substrate, except for an area on which the active layer pattern is to be formed, with a tape may be performed.

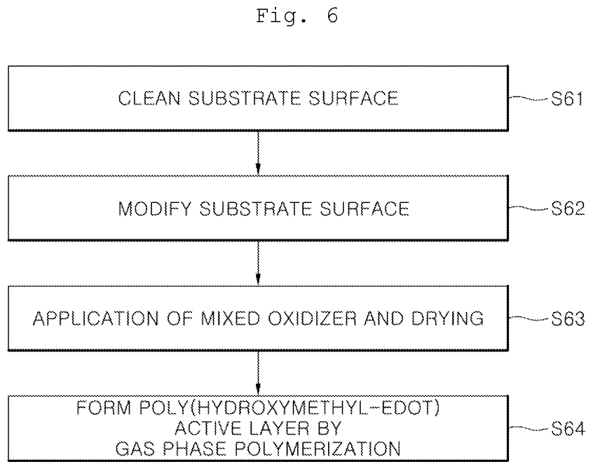

FIG. 6 is a flowchart illustrating an embodiment of the active layer forming step S22.

The active layer forming step will be described in more detail with reference to FIG. 6. First, substrate surface cleaning step S61 may be performed. The substrate surface cleaning step S61 may be a step of cleaning the surface of the substrate with a cleaning solution, such as ethanol, and then removing impurities from the surface of the substrate using an ultrasonic cleaner.

Afterwards, substrate surface modification step S62 may be performed. The substrate surface modification step S62 may be a step of moving the substrate, the surface cleaning of which is completed, into a plasma chamber and modifying, while removing impurities from, the surface of the substrate using plasma. Here, the plasma processing may be performed using Ar/H₂O plasma. The substrate surface modification step S62 may be omitted depending on the material of the substrate.

Step S63 of applying a mixed oxidizer to the surface of the surface-modified substrate and drying the mixed oxidizer is performed. Here, the mixed oxidizer may include PEG-PPG-PEG, DUDO, and FeCl₃. The mixed oxidizer may be manufactured by adding PEG-PPG-PEG into a solvent, such as butanol, performing dispersion using ultrasonic waves, adding DUDO to the resultant solution, performing dispersion using ultrasonic waves, pouring FeCl₃ into the resultant solution, stirring the mixture, and then performing dispersion using ultrasonic waves. Here, FeCl₃ may be added in the form of FeCl₃.6H₂O.

The oxidizer mainly used for synthesis of conductive polymers is FeCl₃ or ferric p-toluenesulfonate (Fe(PTS₃)). However, when such an oxidizer is used alone, the shape of a synthesized polymer thin film is not uniform. Due to high acidity (pH<2) of the oxidizer, the thin film may not efficiently form a conjugated double bond. Thus, a porous thin film having low electric conductivity is synthesized. In contrast, in embodiments of the present disclosure, DUDO is added as an inhibitor to inhibit addition reactions in polymer synthesis. In addition, the mixed oxidizer, to which PEG-PPG-PEG is added, is used as a mediator for improving the quality of a thin film synthesized. Accordingly, a polymer active layer having superior film quality and characteristics can be formed. In particular, by performing dispersion using ultrasonic waves so that substances of the mixed oxidizer may be uniformly dispersed, a polymer active layer having uniform film quality can be formed.

In the mixed oxidizer according to embodiments of the present disclosure, the content ranges of FeCl₃.6H₂O, DUDO, and PEG-PPG-PEG may be 0.5 to 8 mmol, 0.1 to 0.6 mmol, and 0.005 to 0.3 mmol, respectively. More preferably, the content ranges of FeCl₃.6H₂O, DUDO, and PEG-PPG-PEG may be 5 to 6 mmol, 0.3 to 0.4 mmol, and 0.1 to 0.2 mmol, respectively. The composition of the mixed oxidizer is significantly important to obtain superior electric conductivity and the reliability of the aqueous solution. This will be described below in relation to test results according to Example and Comparative Example.

In the step S63, the application of the mixed oxidizer may be performed by spin coating or drop coating.

A poly(hydroxymethyl-EDOT) active layer is formed on the substrate applied with the mixed oxidizer by gas phase polymerization in step S64. The gas polymerization step of the active layer may be a step of forming an active layer on the oxidizer-applied substrate from an HO—CH₂-EDOT (3,4-ethylenedioxythiophene) monomer including a bondable functional group by gas polymerization. Synthesis of poly(hydroxymethyl-EDOT) by gas polymerization can form a thin film having a uniform thickness and high conductivity compared to a thin film synthesized by electropolymerization. In particular, electropolymerization can only synthesize a thin film on a conductive substrate, whereas gas phase polymerization can synthesize a thin film irrespective of the substrate type. Accordingly, it is possible to advantageously manufacture a flexible device by forming an organic electrochemical transistor device on a polymer substrate.

The organic electrochemical transistor according to Example of the present disclosure may be used as a biosensor by fixing a bioreceptor to the polymer active layer. That is, the biosensor according to Example of the present disclosure may be configured such that the bioreceptor is fixed to the polymer active layer of the organic electrochemical transistor. Here, the bioreceptor may be an artificial antibody capable of selectively binding to a variety of antigens or the like. In the present disclosure, Poly(hydroxymethyl-EDOT) used as the polymer active layer includes a large amount of hydroxyl group (—OH) in the surface and bulk, and thus, can advantageously fix the bioreceptor using such a hydroxyl group as a functional group.

The biosensor according to Example of the present disclosure may further include a linker for fixing the bioreceptor to the polymer active layer. The linker may be introduced to the hydroxyl group of the poly(hydroxymethyl-EDOT) polymer active layer and provide a functional group to which the bioreceptor binds. The linker may be a 3-aminopropyltrimethoxysilane (APS) self-assembled molecular layer. The APS self-assembled molecular layer may be introduced to the hydroxyl group of the poly(hydroxymethyl-EDOT) polymer active layer and provide a large amount of amine group (—NH₂) as a functional group to which the bioreceptor binds.

A cross-linker may be additionally introduced to the linker depending on the bioreceptor type. The cross-linker may bind to the functional group of the liker and provide a functional group to which the bioreceptor binds. For example, the cross-linker may be sulfosuccinimidyl 4-(N-maleimidomethyl)cyclohexane-1-carboxylate (sulfo-SMCC). Sulfo-SMCC may bind to the amine group of the linker, i.e., the APS self-assembled molecular layer, and may provide a maleimido functional group to which the bioreceptor binds.

Hereinafter, the present disclosure will be described in more detail with respect to Example.

1. Manufacture of Organic Electrochemical Transistor Device

(1) Forming Source Electrode and Drain Electrode

A conductive polymer electrode of dodecyl sulfate-doped PEDOT was formed on a PET substrate.

First, an Fe(DS)₃ oxidizer was manufactured as follows. SDS 10.2520 g was dissolved with 40° C. deionized water, and the resultant solution was stirred until being transparent, thereby producing a SDS solution 0.148 mol/L. The SDS solution was stirred and, at the same time, an FeCl₃ aqueous solution 0.197 mol/L was slowly added to the SDS solution so that the mole ratio between SDS and FeCl₃ was 3:1. The produced precipitate was repeatedly cleaned with deionized water 10 or more times and then was dissolved with methanol 45 ml. Centrifugation was performed at 5000 rpm to remove non-dissolved impurities. The methanol solution from which impurities are removed was slowly stirred, and at the same time, deionized water 200 ml was added. Fe(DS)₃ recrystallized and precipitated from the solution was repeatedly cleaned 5 times or more, and vacuum freeze drying was performed for two days or more.

Afterwards, an electrode pattern was formed by forming a PEDOT film as follows. After a masking tape was attached to the PET substrate so that only an area thereof on which an electrode is to be formed was exposed, the exposed area was coated with a solution containing Fe(DS)₃ oxidizer. Before the oxidizer coating, the substrate was cleaned with ultrasonic waves in ethanol for 30 minutes. The substrate coated with the oxidizer was mounted in the gas polymerization chamber so that an oxidizer film faces downward. Thereafter, EDOT monomer and water provided in the chamber were evaporated, thereby forming a PEDOT film on the substrate. At this time, the temperature of the chamber was adjusted to be 50° C. by circulating hot water through the walls of the chamber, and the temperature of the chamber was monitored using a temperature sensor provided inside the chamber. Excessive oxidizer and EDOT monomer were removed by cleaning with ethanol, and drying was performed in a pressure-reduced condition at 70° C. for one hour, thereby removing ethanol. The masking tape attached to the substrate was removed.

The sheet resistance R of the PEDOT film formed on the PET substrate was measured using a four-point probe. Subsequently, electric conductivity was calculated using a film thickness measured by FE-SEM, and a doping level was analyzed by X-ray photoelectron spectroscopy (XPS).

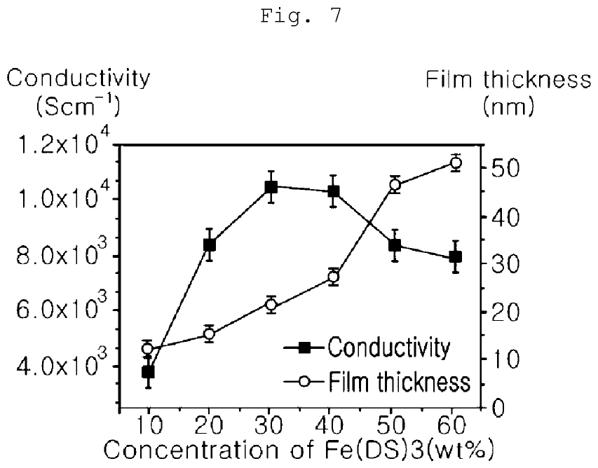

FIG. 7 is an electric conductivity graph of a PEDOT film according to the concentration of an Fe(DS)₃ oxidizer included in an oxidizer solution in a situation in which polymerization time and polymerization temperature are fixed. As the oxidizer concentration increases from 10% to 30%, the electric conductivity continuously increases. However, it was appreciated that, above 30%, the electric conductivity starts to decrease. Thus, optimum oxidizer concentration for forming the source electrode and the drain electrode of the organic electrochemical transistor device may be determined to be 30%, and at this point, the electric conductivity was 10,307±500 S/cm. Thus, considering that the highest electric conductivity of the PEDOT film produced by gas phase polymerization, which has been reported so far, is 5,400 S/cm of a tosylate-doped PEDOT film, the electric conductivity of the PEDOT film formed according to Example of the present disclosure is almost twice the electric conductivity of the related art. In addition, not only in the oxidizer concentration of 30% but also in most of the oxidizer concentration range in FIG. 7, electric conductivity characteristics superior to those of the related art were obtained. Thus, high electric conductivity characteristics of the PEDOT film according to Example of the present disclosure may be regarded as the dodecyl sulfate doping effect using the Fe(DS)₃ oxidizer.

As a result of the XPS analysis, the doping level of dodecyl sulfate in the PEDOT film when the 30% oxidizer solution was used was about 37%.

(2) Forming Polymer Active Layer

A poly(hydroxymethyl-EDOT) polymer active layer was formed on a PET substrate having a source electrode and a drain electrode.

First, PEG-PPG-PEG 0.8 g was added to butanol, a solvent, 30 ml, and then, dispersion was performed using ultrasonic waves for 30 minutes. DUDO, an additive, 0.3 g, was added, and then, dispersion was performed using ultrasonic waves in the same manner. Subsequently, FeCl₃.6H₂O 1.5 g was added, and stirring was performed. Afterwards, dispersion was performed using ultrasonic waves, thereby manufacturing a mixed oxidizer. For comparison, a mixed oxidizer was manufactured by adding PEG-PPG-PEG 0.2 g and DUDO 0.2 g. After a poly(hydroxymethyl-EDOT) polymer active layer was formed, characteristics were compared.

Afterwards, a mask was formed on the substrate using a sealing tape, and then, a manufactured mixed oxidizer was drop-coated. After the mixed oxidizer was drop-coated, drying was performed on a 50° C. hot plate for 3 minutes in order to prevent phase separation of the oxidizer and remove the solvent. A sample applied with the oxidizer was moved into a gas polymerization chamber heated to 60° C. and exposed to poly(hydroxymethyl-EDOT) vapor, thereby forming a polymer active layer. Annealing was performed on a 120° C. hot plate to remove a portion of the hydroxymethyl-EDOT monomer not reacted in the polymerization process and a portion of the solvent remaining in the thin film.

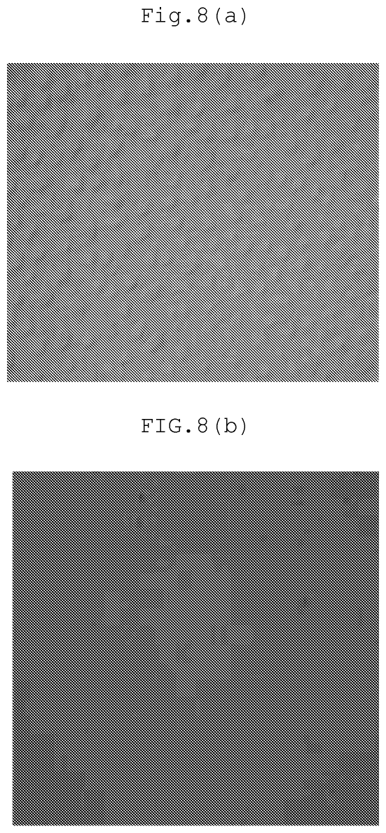

The surfaces of the poly(hydroxymethyl-EDOT) according to Example and Comparative Example were observed with an optical microscope and electric resistances thereof were measured. Results of observation using an optical microscope at 500× magnification were illustrated in FIG. 8. For comparison in the same conditions, the mixed oxidizer 30 μl was drop-coated, and gas polymerization was performed in the same conditions. In Comparative Example of FIG. 8(a), the poly(hydroxymethyl-EDOT) thin film was not uniformly synthesized. In contrast, in Example condition of FIG. 8(b), it was appreciated that the poly(hydroxymethyl-EDOT) was formed uniformly. As a result of electric resistance measurement, in Comparative Example, the electric resistance had significant differences depending on the sample, and a high resistance value of thousands of Ohms was measured. In contrast, in Example, significantly low resistance values of about 30 to 40 Ohms were measured from samples. From this, it will be understood that a uniform poly(hydroxymethyl-EDOT) polymer active layer having superior electric conductivity characteristics can be formed by gas phase polymerization using the mixed oxidizer according to Example of the present disclosure.

(3) Manufacture of Organic Electrochemical Transistor Device

An organic electrochemical transistor device composed of only a polymer material was manufactured by forming dodecyl sulfate-doped PEDOT source and drain electrodes and a poly(hydroxymethyl-EDOT) polymer active layer on a PET substrate by the above-described method.

After a KCl electrolyte aqueous solution was provided to the polymer active layer of the manufactured organic electrochemical transistor device, transistor characteristics were measured by applying a gate voltage and a drain voltage. In addition, to review aqueous solution stability of the transistor device, the transistor device was immersed in the aqueous solution for 48 hours, and then, transistor characteristics were reviewed. In order to review mechanical durability, transistor characteristics were reviewed after a 10,000 times or more bending test.

2. Characteristics of Organic Electrochemical Transistor Device

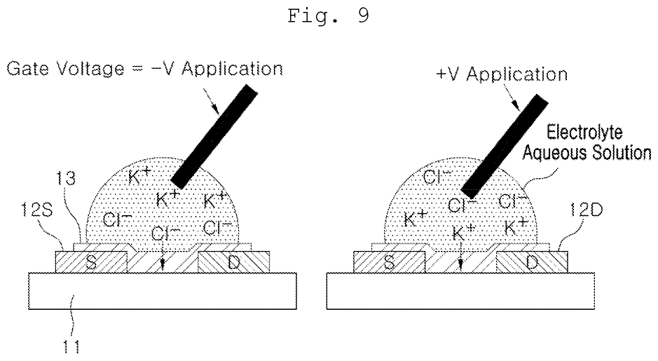

FIG. 9 is a conceptual view of an operation in a situation in which a KCl aqueous solution, i.e., an electrolyte aqueous solution, is applied to the polymer active layer 13 of the organic electrochemical transistor device and the gate voltage is increased. When a negative (−) gate voltage is applied, anions (Cl⁻) are doped into the polymer active layer 13, thereby increasing the drain current. In contrast, when a positive (+) gate voltage is applied, cations (K⁺) are doped into the polymer active layer 13 (i.e., de-doping), thereby reducing the drain current.

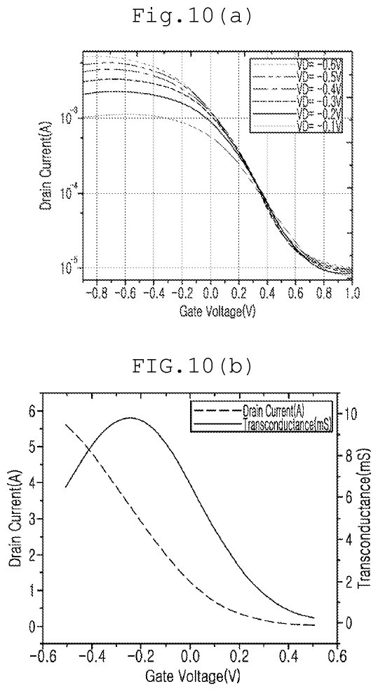

FIG. 10 is a measurement result of transistor characteristics of an organic electrochemical transistor device manufactured according to embodiments of the present disclosure. From FIG. 10(a), it may be appreciated that a transistor characteristic appears in which a drain current increases with application of a negative (−) gate voltage. It may also be appreciated from FIG. 10(b) that the transconductance, i.e., the rate of change of the drain current, is significantly large, with the maximum value thereof being about 10 mS. Considering that the maximum transconductance of the PEDOT:PSS-based organic electrochemical transistor is about 4 mS, it may be appreciated that a high-sensitivity organic electrochemical transistor having significantly improved sensitivity characteristics may be realized according to embodiments of the present disclosure. That is, according to the present disclosure, it is possible to realize an organic electrochemical transistor having a maximum transconductance of 6 mS or more, preferably, 8 mS or more, and more preferably, 10 mS or more.

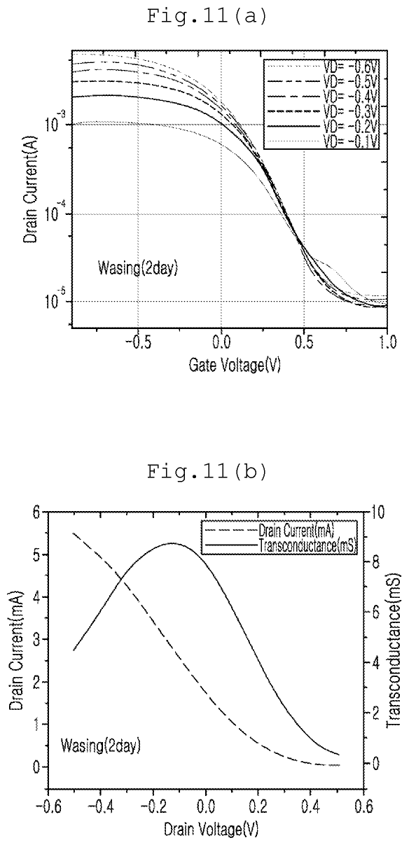

FIG. 11 is a measurement result of aqueous solution stability of an organic electrochemical transistor device manufactured according to embodiments of the present disclosure. Referring to FIG. 11(a), it may be appreciated that stable transistor characteristics are obtained even after immersion in an aqueous solution for 48 hours, and referring to FIG. 11(b), it may be appreciated that a still significant transconductance value of 9 mS is obtained. That is, even after having been immersed in the aqueous solution for 48 hours or more, the organic electrochemical transistor device according to embodiments of the present disclosure has a transconductance change of about 10% or less and still functions as a high-sensitivity device.

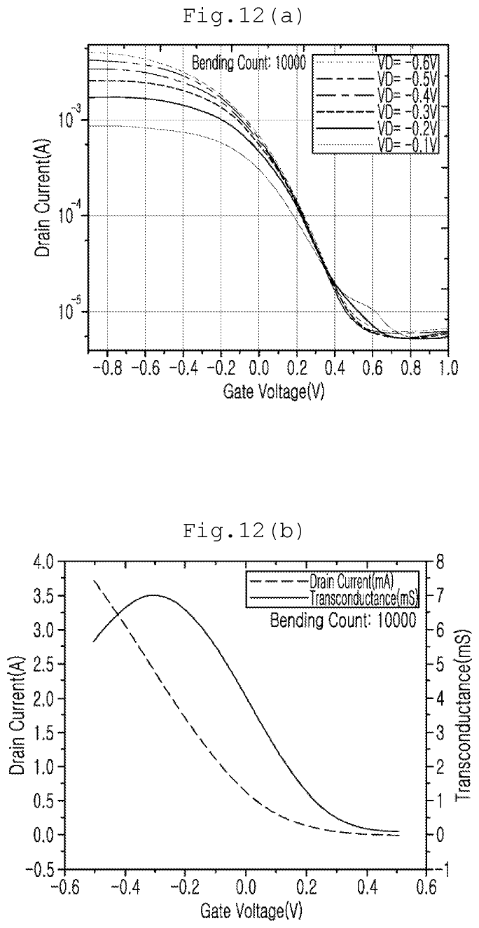

FIG. 12 is a measurement result of mechanical durability of an organic electrochemical transistor device manufactured according to embodiments of the present disclosure. Referring to FIG. 12(a), it may be appreciated that stable transistor characteristics are obtained even after a 10,000 times or more bending test, and referring to FIG. 12(b), it may be appreciated that a significantly large transconductance value of about 7 mS is still obtained. That is, even after the 10,000 times or more bending test, the organic electrochemical transistor device according to embodiments of the present disclosure has a transconductance change of about 30% or less and still functions as a high-sensitivity device.

3. Manufacture of Biosensor

A biosensor was manufactured using an organic electrochemical transistor according to embodiments of the present disclosure. After an APS self-assembled molecular layer was introduced as a linker to a poly(hydroxymethyl-EDOT) polymer active layer, sulfo-SMCC was additionally introduced as a cross-linker. After the bioreceptor containing a fluorescent substance is bound to the cross-linker, whether or not the bioreceptor is bound was reviewed by observation using an optical microscope.

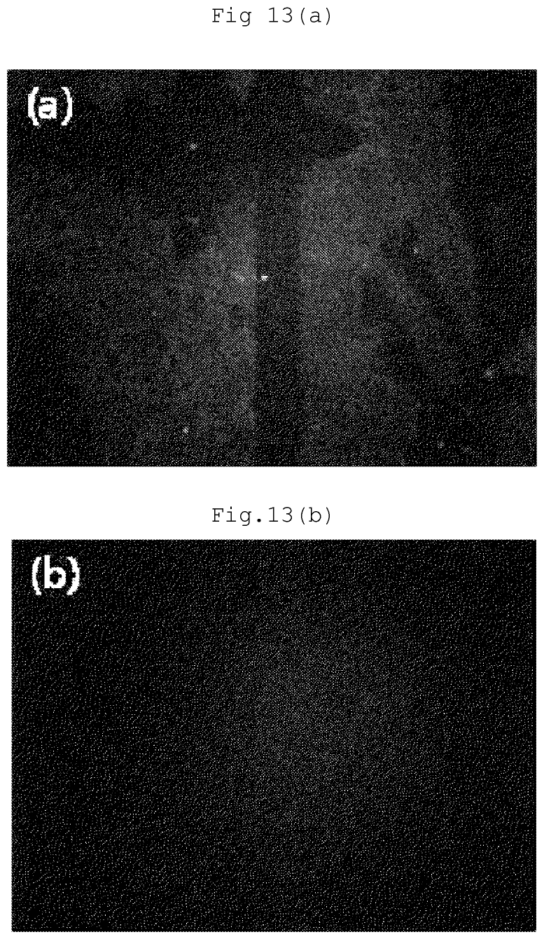

FIGS. 13(a) and 13(b) is an observation result using an optical microscope in a situation in which a linker is introduced and a situation in which no linker is introduced. In a situation in FIG. 13(a) in which the linker is introduced, it may be appreciated that fluorescent light is clearly observed and thus the bioreceptor is successfully fixed to the poly(hydroxymethyl-EDOT) polymer active layer.

Although the present disclosure has been described hereinabove with reference to the specific embodiments and the drawings, the description is illustrative. Those skilled in the art will appreciate that various modifications are possible without departing from the scope of the technical idea of the present disclosure.

Therefore, the scope of protection of the present disclosure shall be defined by the language of the Claims and the equivalents thereof.

1. An organic electrochemical transistor device comprising:
a substrate;
a source electrode and a drain electrode provided on a top surface of the substrate; and
a poly(hydroxymethyl-EDOT) polymer active layer provided on the top surface of the substrate and in electrical contact with the source electrode and the drain electrode.

2. The organic electrochemical transistor device of claim 1, wherein the substrate comprises a flexible substrate.

3. The organic electrochemical transistor device of claim 1, wherein each of the source electrode and the drain electrode comprises a PEDOT film doped with dodecyl sulfate.

4. The organic electrochemical transistor device of claim 3, wherein the PEDOT film is formed by gas phase polymerization using dodecyl sulfate metal salt as an oxidizer.

5. The organic electrochemical transistor device of claim 4, wherein the dodecyl sulfate metal salt comprises Fe(DS)₃.

6. The organic electrochemical transistor device of claim 3, wherein a content of the dodecyl sulfate in the PEDOT film ranges from 5 to 50%.

7. The organic electrochemical transistor device of claim 1, wherein a maximum transconductance value is 6 mS or more.

8. The organic electrochemical transistor device of claim 1, wherein a change in transconductance after immersion in an aqueous solution for 48 hours or more is 10% or less.

9. The organic electrochemical transistor device of claim 1, wherein a change in transconductance after a 10,000 times or more bending test is 30% or less.

10. A biosensor comprising the organic electrochemical transistor device as claimed in any of the preceding claims 1 to 9.

11. The biosensor of claim 10, wherein a bioreceptor is fixed to the poly(hydroxymethyl-EDOT) polymer active layer.

12. The biosensor of claim 11, further comprising a linker for binding the bioreceptor to the polymer active layer.

13. The biosensor of claim 12, further comprising a cross-linker for binding the bioreceptor to the linker.

14. The biosensor of claim 13, wherein the linker comprises an APS self-assembled molecular layer, and the cross-linker comprises sulfo-SMCC.

15. A method of manufacturing an organic electrochemical transistor device, the method comprising:
an electrode forming step of forming a source electrode and a drain electrode on a top surface of a substrate; and
an active layer forming step of forming a poly(hydroxymethyl-EDOT) polymer active layer on the top surface of the substrate to be in electrical contact with the source electrode and the drain electrode,
wherein the active layer forming step is performed on the substrate to which a mixed oxidizer is applied by gas phase polymerization.

16. The method of claim 15, wherein the mixed oxidizer comprises FeCl₃, DUDO, and PEG-PPG-PEG.

17. The method of claim 16, wherein a composition of the mixed oxidizer comprises FeCl₃.6H₂O 0.5 to 8 mmol, DUDO 0.1 to 0.6 mmol, and PEG-PPG-PEG 0.005 to 0.3 mmol.

18. The method of claim 17, wherein the composition of the mixed oxidizer comprises FeCl₃.6H₂O 5 to 6 mmol, DUDO 0.3 to 0.4 mmol, and PEG-PPG-PEG 0.1 to 0.2 mmol.

19. The method of claim 15, wherein the electrode forming step comprises:
a step of coating an oxidizer comprising dodecyl sulfate metal salt on a substrate;
a step of forming a PEDOT film on the oxidizer-coated substrate by gas phase polymerization; and
cleaning and drying the PEDOT film.

20. The method of claim 19, wherein the dodecyl sulfate metal salt comprises Fe(DS)₃.
